(19) United States
(12) Patent Application Publication
(10) Pub. No.: US 2007/0165479 A1
(43) Pub. Date: Jul. 19, 2007

(54) Local wordline driver scheme to avoid fails due to floating wordline in a segmented wordline driver scheme

(76) Inventor: Norbert Rehm, Apex, NC (US)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/333,043

(22) Filed: Jan. 17, 2006

(51) Int. Cl. G11C 8/00

(52) U.S. Cl. 365/230.06

(57) ABSTRACT

Embodiments of the invention generally provide a method for accessing a local wordline in a segmented memory. In one embodiment, the method includes, during an access to the local wordline, applying a first voltage to the local wordline via a local wordline driver located at a first end of the local wordline. After the access is completed, a second voltage is applied to the local wordline, wherein the second voltage is applied to the local wordline via a pull-down circuit located at a second end of the local wordline opposite from the first end, and wherein one or more memory cells are attached to local wordline between the local wordline driver and the wordline pull-down circuit.

### BACKGROUND OF THE INVENTION

1. Field of the Invention

Embodiments of the present invention generally relate to design and operation of segmented wordlines. Specifically, embodiments relate to reducing failures in a segmented wordline driver scheme.

2. Description of the Related Art

Modern electronic devices such as digital music players, portable digital assistants (PDAs), cell phones, and laptops require increasing amounts of memory to handle the computing demands of users of the devices. Accordingly, modern electronic devices typically employ some sort of random access memory (RAM), such as dynamic random access memory (DRAM) to store data for the device.

Memory in a DRAM is typically arranged in an array of memory cells. An address in the memory array (e.g., a row of memory cells in the array) may be accessed by applying an activation voltage (referred to as a “wordline on voltage”, VWLON) to the row of memory cells via a wordline connected to the row of memory cells. When the row of memory cells is activated, data may be written to and read from the memory cells via bitlines connected to the memory cells. Then, after the memory cells have been accessed, the row of memory cells may be deactivated by lowering the voltage applied to the memory cells to a low voltage (the wordline off voltage, VWLOFF).

In some cases, a memory array may be divided into segments and accessed via segmented wordlines. A segmented wordline may include a main wordline and a plurality of local wordlines activated via the main wordline. To activate one of the plurality of local wordlines, a row decoder may be used to activate the main wordline, and a local wordline decoder may be used to select one of the local wordlines for the activated main wordline. When the main wordline is activated and a local wordline has been selected, a local wordline driver located at one end of the local wordline may apply VWLON to the local wordline. After the local wordline has been accessed, the main wordline and local wordline decoder may deselect and deactivate the local wordline driver. When the local wordline driver is deselected and deactivated, the local wordline driver may apply VWLOFF to the local wordline.

In some cases, imperfections in the manufacture of a DRAM device may cause defects in a local wordline driver, in the control signals applied to the local wordline driver, or to control circuits for the local wordline driver. The defects may result in improper operation of the DRAM device. For instance, defects in the local wordline driver may cause the local wordline driver to improperly deactivate the local wordline. As an example, instead of applying VWLOFF to the local wordline when the local wordline is deactivated, the local wordline driver may instead electrically disconnect the local wordline from VWLON and VWLOFF (referred to as floating the local wordline).

In some cases, when the local wordline is deactivated and floating, leakage currents in the local wordline may increase the voltage of the local wordline. Where the local wordline voltage is increased, memory cells accessed via the local wordline may be inadvertently accessed (e.g., as the local wordline voltage approaches VWLON). Where the memory cells for the defective local wordline are inadvertently accessed, data may be read from or written to the memory cells while other memory cells (e.g., at another memory address) are being accessed. In some cases, the data inadvertently read from or written to the memory cells for the defective local wordline may interfere with data being read from or written to other memory cells in the memory array (e.g., the data in the inadvertently accessed memory cells and the correctly accessed memory cells may conflict), thereby incorrectly modifying or destroying the data store therein.

Accordingly, an improved method and apparatus for accessing local wordlines in a segmented memory array is needed.

### SUMMARY OF THE INVENTION

Embodiments of the invention generally provide a method for accessing a local wordline in a segmented memory. In one embodiment, the method includes, during an access to the local wordline, applying a first voltage to the local wordline via a local wordline driver located at a first end of the local wordline. After the access is completed, a second voltage is applied to the local wordline, wherein the second voltage is applied to the local wordline via a pull-down circuit located at a second end of the local wordline opposite from the first end, and wherein one or more memory cells are attached to local wordline between the local wordline driver and the wordline pull-down circuit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram depicting a memory device according to one embodiment of the invention.

FIG. 2 is a block diagram depicting a memory array according to one embodiment of the invention.

FIG. 3 is a circuit diagram depicting a local wordline driver and pull-down transistor according to one embodiment of the invention.

FIG. 4 is a block diagram depicting a plurality of local wordlines and pull-down transistors according to one embodiment of the invention.

FIG. 5 is a block diagram depicting a modified local wordline driver and pull-down transistor according to one embodiment of the invention.

FIG. 6 is a circuit diagram depicting a memory array with pull-down transistors according to one embodiment of the invention.

FIG. 7 is a circuit diagram depicting a side view of a pull-down transistor in a memory array according to one embodiment of the invention.

FIG. 8 is a block diagram depicting local wordline decoders used to access a memory array with pull-down transistors according to one embodiment of the invention.

### DETAILED DESCRIPTION OF THE PREFERRED EMBODIMENT

Embodiments of the invention generally provide a method for accessing a local wordline in a segmented memory. In one embodiment, the method includes, during an access to the local wordline, applying a first voltage to the local wordline via a local wordline driver located at a first end of the local wordline. After the access is completed, a second voltage is applied to the local wordline, wherein the second voltage is applied to the local wordline via a pull-down circuit located at a second end (e.g., from both ends of the local word line) of the local wordline opposite from the first end, and wherein one or more memory cells are attached to local wordline between the local wordline driver and the wordline pull-down circuit. By providing a pull-down circuit for the local wordline, any defects in the local wordline driver which cause the local wordline to remain floating after an access and possibly result in an inadvertent access to the local wordline may be avoided.

To facilitate understanding, the following description will refer to memory devices, such as dynamic random access memory (DRAM) devices, as specific, but not limiting examples of devices in which the circuits described herein may be utilized. Further, while the following description may refer certain control signals as being asserted to high logic signals or lowered to low logic signals, those skilled in the art will recognize that such signal levels are merely exemplary and that any circuitry described herein may be configured to use any number of signals of any polarity and/or voltage level. Also, while some signals are referred to as originating from a given control circuit or device, it should be recognized that any described control signal may originate from any given circuit or device.

Any signal names described herein are exemplary, and in general embodiments of the invention may be implemented with any signal(s) bearing any name(s), and/or from any signal(s) derived from one or more such signals. Similarly, described implementations of certain circuits are merely exemplary. In some cases, simplified implementations of such circuits may be presented in order to better explain aspects of embodiments of the present invention. However, those skilled in the art will recognize that embodiments of the present invention may be adapted for use with any implementation or configuration of such circuits, including complicated and/or commercial implementations of such circuits.

### A Dram Memory Device

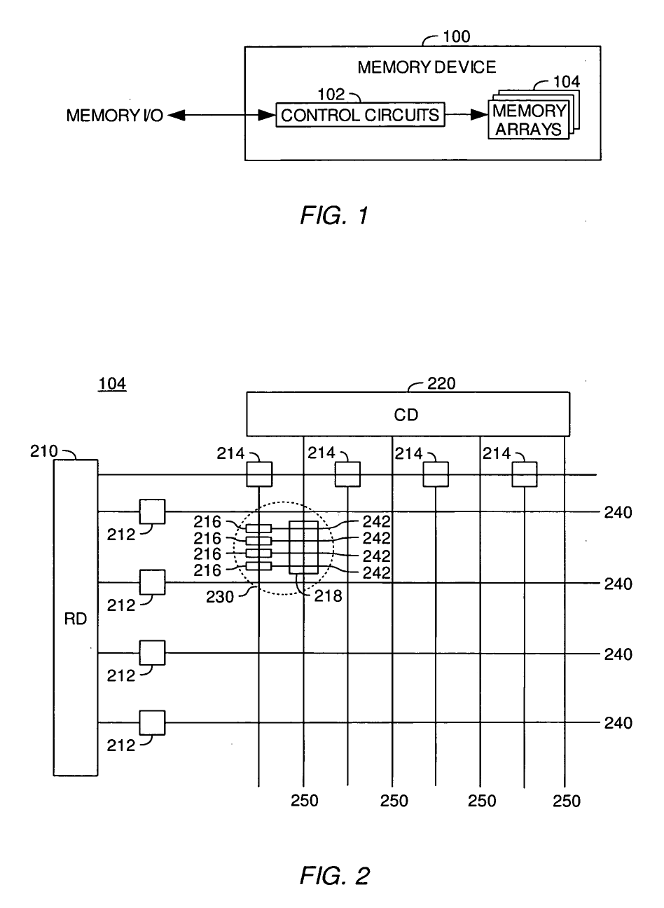

FIG. 1 is a block diagram depicting a memory device 100 according to one embodiment of the invention. The memory device may have control circuits 102 accessed using a memory I/O interface. The control circuits 102 may be used to access one or memory arrays 104 of the memory and may issue control signals to components within the memory array 104. FIG. 2 is a block diagram depicting an exemplary memory array 104 and associated access circuitry. In one embodiment, a row decoder 210 and a column decoder 220 may be used to access the memory array 104. Each time a memory address in the memory array 104 is accessed, the address may be decoded by the row decoder 210 and column decoder 220 to determine at which row (also referred to as a wordline or main wordline 240) and which column (also referred to as a bitline 250) in the array the memory address resides. Other elements (not shown), such as sense amplifiers, may also be used to access (e.g., read, write, or refresh) the memory array 104.

In some cases, the memory device 100 may utilize a segmented wordline structure. In a segmented wordline structure, each memory array 104 may contain multiple memory segments 230 and each segment may contain an array of memory cells 218. To activate the memory cells 218 in each memory segment 230, the row decoder 210 may first be used to decode the memory address and select a segment 230 within the memory array 104. After a segment 230 has been selected, the memory address may be further decoded to select a main wordline 240 from the memory array 104. When a main wordline 240 has been selected, the memory address may then be decoded by a local wordline decoder 214 to select and access a local row (referred to as a local wordline 242) within the segment 230. The process of decoding a memory address to select a segment 230, main wordline 240, and a local wordline 242 within a segment 230 may be referred to as hierarchical decoding.

Each local wordline 242 may have a local wordline driver 216 connected to one end of the local wordline 242 and used to drive the local wordline 242. For any one memory address being accessed, one main wordline 240 and one local wordline 242 may be activated while many main wordlines 240 and many local wordlines 242 are not activated. The main wordline 240 and the local wordline 242 which are selected may be in what is referred to as an operational or activated mode. The wordlines 240 and local wordlines 242 which are not selected may, in some cases, be in a state or mode referred to as an inactive state or inactive mode.

When a main wordline 240 is selected, a main wordline driver 212 for the selected main wordline 240 may lower an inverted main wordline signal (bMWL) which is applied to the main wordline 240. A signal (referred to as WLRSTP) output by a local wordline decoder 214 to each local wordline driver 216 may be used to determine whether the local wordline driver 216 for a selected main wordline 216 is activated. Each local wordline decoder 214 may control several local wordline drivers 216 (also referred to as a column or cluster of local wordline drivers 216). When WLRSTp is lowered to a low voltage and bMWL is a low voltage, the local wordline driver 216 may be activated. When WLRSTp is asserted to a high voltage (e.g., V_{DD} or another high voltage), or when bMWL is asserted to a high voltage, the local wordline driver 216 and local wordline 242 may be inactive. When a local wordline 242 is inactive, it may be reset (e.g., lowered to a low voltage) using the wordline reset signal WLRST (a buffered version of WLRSTP).

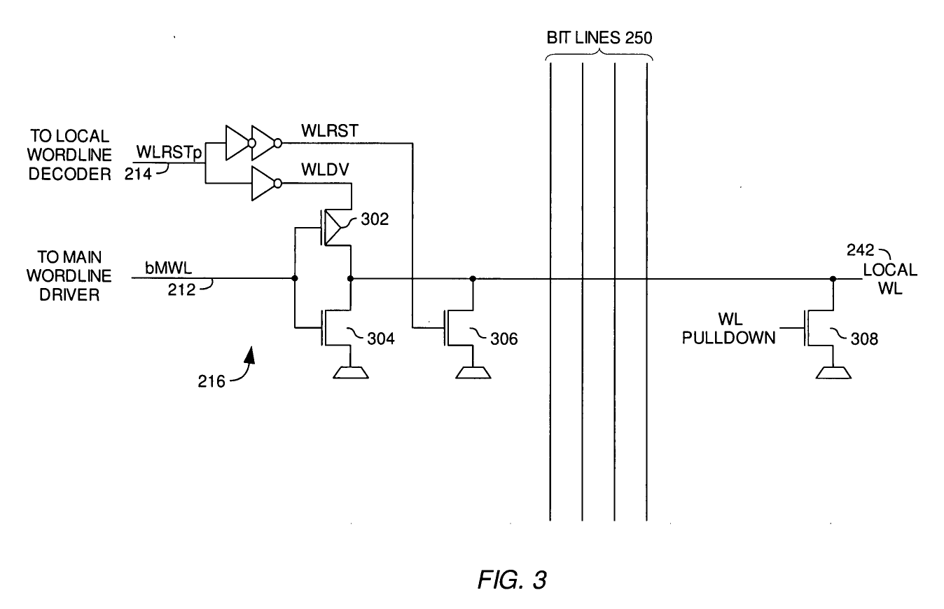

FIG. 3 is a circuit diagram depicting a local wordline driver 216 with a pull-down transistor 308 according to one embodiment of the invention. The local wordline driver 216 may have an inverter (PMOS pull-up transistor P1 302 and NMOS pull-down transistor N1 304) which drives local wordline 242 as well as a reset transistor (NMOS transistor N2 306) which resets local wordline 242. As described below, the pull-down transistor may be used to deactivate the local wordline 242. The inverter may be controlled by the bMWL signal and the reset transistor 306 may be driven by WLRST signal (the buffered WLRSTp signal) as depicted.

Operation of the Local Wordline Driver

If a memory access is made which utilizes a given main wordline 240 and local wordline 242, the wordline driver 212 for the main wordline 240 may lower the bMWL signal, thereby selecting the main wordline 240. Otherwise, the bMWL signal for a main wordline 240 which is not selected may remain at a high voltage.

When the bMWL signal is lowered, the wordline driving signal WLDV (the inverse of the WLRSTp signal) may be driven by the local wordline driver 216 through the PMOS transistor 302. If bMWL is lowered and the local wordline 242 is not selected during a memory access, a wordline off voltage (VWLOFF) may be applied to WLDV and driven onto the local wordline 242. If bMWL is lowered and the local wordline 242 is selected during a memory access, the local wordline decoder 214 for the local wordline driver 216 may lower the WLRSTp signal, thereby asserting the WLDV signal to a high voltage (referred to as, e.g., V_{PP} or VWLON). The asserted WLDV signal may then be driven onto the local wordline 242, allowing memory cells controlled by the local wordline 242 to be accessed via bitlines 250.

In some cases, the main wordline 240 for a local wordline driver 216 may not be selected (bMWL=V_{PP}), but the column of local wordline drivers controlled by a local wordline decoder 214 containing the local wordline driver 216 may be selected (WLRSTp=V_{PP}). In such a case, the local wordline 242 is not selected, and the output of the local wordline driver 216 is VWLOFF.

When an access to the main wordline 240 is not occurring, the main wordline 240 and local wordline 242 may be deselected. Thus, for the main wordline 240, the bMWL signal may be raised to a high logic value, V_{PP}. For the local wordline 242, the wordline driving signal WLRSTP signal may be asserted to a high voltage, thereby raising WLRST to a high voltage, lowering WLDV to a low voltage, and causing the local wordline 242 to be reset to the wordline off voltage, VWLOFF. In some cases, the wordline off voltage VWLOFF may be a low voltage, V_{GND}. In other cases, the wordline off voltage may the downward-driven low voltage (also referred to as a downward-boosted low voltage) which may be maintained by a charge pump. In some cases, when the main wordline 240 and the local wordline 242 are not selected, the local wordline driver 216 may be in the standby mode.

Utilizing a Separate Pull-Down Transistor for a Local Wordline

As previously described, in some cases, defects in a local wordline driver 216 may cause a local wordline 242 to be improperly deactivated. For example, NMOS transistors 304 and/or 306 may be manufactured with defects or the control signals applied to the transistors 304, 306 may be defective (e.g., the control lines may contain shorts or gaps). Thus, in some cases, when the local wordline 242 is deactivated (e.g., when the local wordline decoder 214 and main wordline 212 deselect the local wordline 242), instead of properly lowering the local wordline 242 to the wordline off voltage VWLOFF, the local wordline 242 may be merely electrically disconnected (referred to as floating, e.g., transistors 304 and 306 may remain closed and non-conducting). In some cases, the floating local wordline 242 may float upward to a high voltage. For example, if WLDV is asserted and bMWL is also asserted, a leakage current across closed PMOS transistor 302 may slowly charge the local wordline 242. As described above, when the local wordline 242 floats upward to a high voltage, memory cells accessed via the local wordline 242 may be inadvertently accessed and interfere with and possible destroy data being accessed in other, properly accessed memory cells for other local wordlines 242.

In one embodiment of the invention, in order to minimize the possibility of floating local wordlines 242 in a segmented memory array 104, a pull-down transistor 308 may be connected to the local wordlines 242 in the segmented memory array 104. As depicted in FIG. 3, the pull-down transistor may be connected to an end of the local wordline 242 opposite the end to which the local wordline driver 216 is connected.

By connecting the pull-down transistor to the opposite end of the local wordline (e.g., on the other side of the bitlines 250 and memory cells accessed via the local wordline 242), any localized manufacturing defects in the local wordline driver 216 may not affect the pull-down transistor 308, thereby allowing the local wordline 242 to be properly pulled down to the wordline off voltage VWLOFF and preventing inadvertent data loss. In other words, because defects in the memory arrays may tend to be localized (e.g., confined to one area), by placing the pull-down transistor 308 in an area away from the local wordline driver 216, there is a small probability that any localized defects which affect the local wordline driver 216 will affect the pull-down transistor 308 and vice-versa. Thus, the pull-down transistor 308 provides redundancy which ensures that the local wordline 242 does not float to a high voltage, causing memory cells connected to the local wordline to be inadvertently accessed.

As depicted, the pull-down transistor 308 may be controlled by the WL Pulldown signal. When the WL Pulldown signal is asserted, the NMOS pull-down transistor 308 may connect the local wordline 242 to the wordline off voltage VWLOFF. When the WL Pulldown signal is lowered to a low voltage, the pull-down transistor 308 may disconnect the local wordline 242 from the wordline off voltage VWLOFF, allowing the local wordline voltage to be controlled by the local wordline driver 216.

In some cases, the WL Pulldown signal may be controlled by or equivalent to the WLRST signal. Where the WL Pulldown signal is equivalent to the WLRST signal, the pull-down transistor 308 may apply VWLOFF to the local wordline 242 whenever the local wordline 242 is not selected by the local wordline decoder 214. In some cases, a single decoder 214 may be used to driver WL Pulldown and WLRST. Optionally, in some cases, as described below, separate decoders may be used to control WL Pulldown and WLRST. In another embodiment of the invention, the pull-down transistor 308 may apply VWLOFF when the segment 230 in which the local wordline 242 is located is not being accessed, for example, when the segment 230 in which the local wordline 242 is located is being precharged.

Controlling the Pull-Down Transistor Based on Segment Access

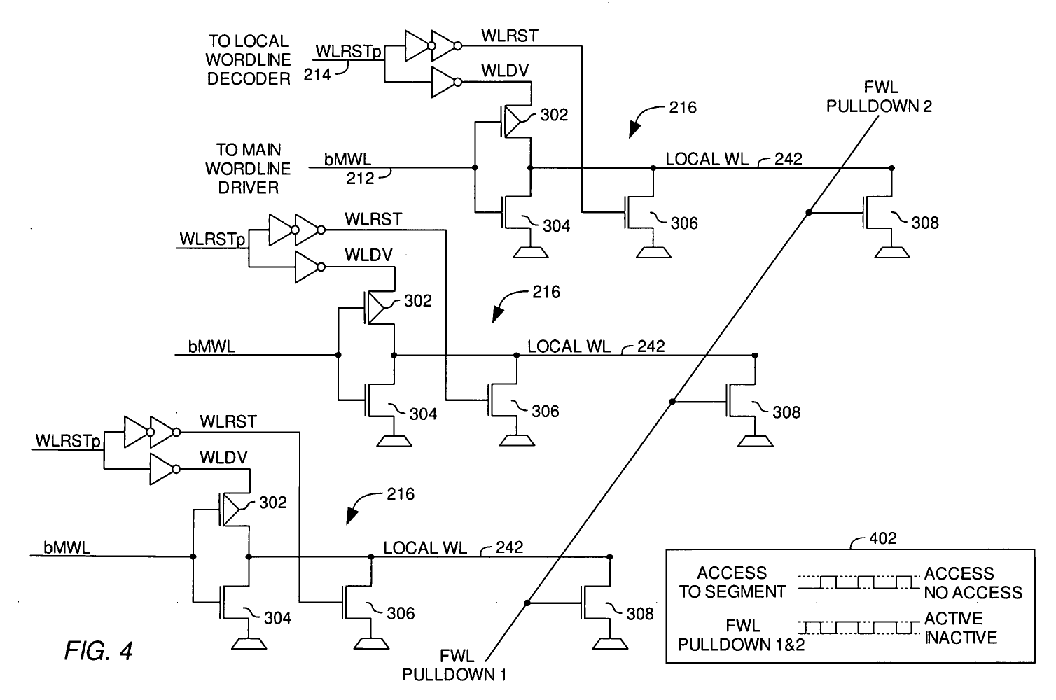

FIG. 4 is a block diagram depicting a plurality of local wordlines 242 and pull-down transistors 308 according to one embodiment of the invention. As described above, in one embodiment, each of the pull-down transistors 308 may be activated and apply the wordline off voltage VWLOFF to the local wordlines 242 when the segment 230 in which the local wordlines 242 are located is not being accessed.

As depicted, each of the pull-down transistors 308 in a segment 230 may be controlled by a single control line. In one embodiment, the control signals FWL Pulldown 1 and FWL Pulldown 2 (floating wordline pull-down) may be used to control the pull-down transistors 308. As depicted by the timing diagram 402, the FWL Pulldown signals may be asserted when the segment 230 is not being accessed (e.g., the FWL Pulldown signals may be inverted with respect to a signal which corresponds to access to a given segment 230, for example, while bitlines 250 in the segment 230 are being precharged). Asserting the FWL Pulldown signals each time a segment 230 is not being accessed may ensure that the voltage of a floating wordline 242 (if any) does not increase to a level approaching VWLON. In other words, by periodically asserting FWL Pulldown and lowering the local wordline voltages to VWLOFF, the pull-down transistors may prevent the voltage of any floating wordlines 242 from rising to a voltage level which may cause data loss as described above.

In one embodiment of the invention, the control line for the pull-down transistors 308 may be driven from each end. For example, separate, redundant driver circuits may be used to driver FWL Pulldown 1 and FWL Pulldown 2. By using redundant driver circuits to drive FWL Pulldown 1 and FWL Pulldown 2, where on of the driver circuits fails (e.g., due to a manufacturing defect in the driver circuit) the other driver circuit may still be used to assert the FWL Pulldown signal and prevent any floating local wordlines 242 from being inadvertently accessed.

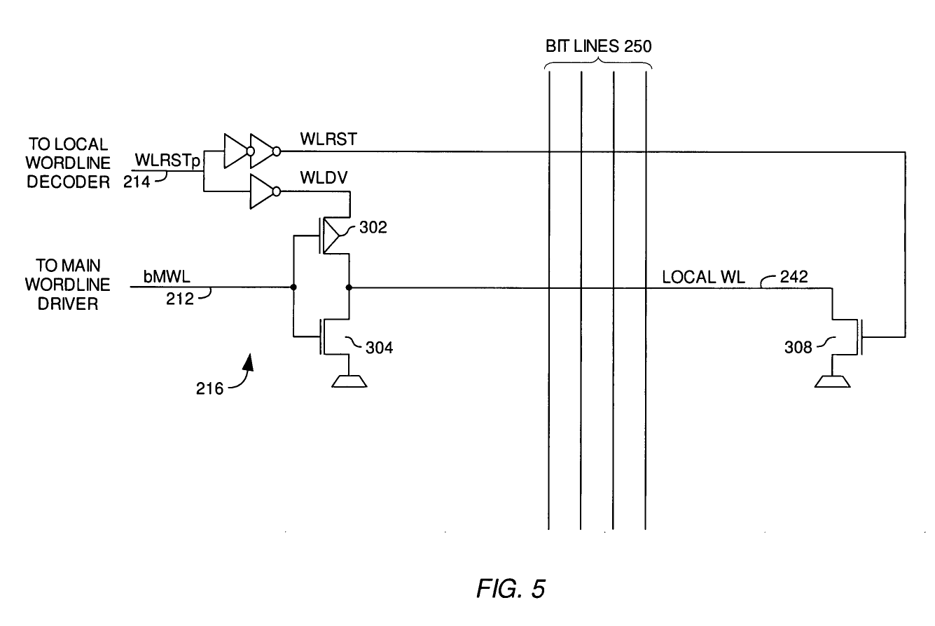

In some cases, the pull-down transistor 308 may be used to replace a pull-down transistor in a local wordline driver 216. FIG. 5 is a block diagram depicting a modified local wordline driver 216 and pull-down transistor 308 according to one embodiment of the invention. As depicted, the modified local wordline driver 216 may contain a single inverter consisting of transistors 302 and 304 and controlled by the bMWL and WLDV signals. The pull-down transistor 308 may connected to the opposite end of the local wordline 242 and be controlled by the WLRST signal. Each time the local wordline 242 is not being accessed, the WLRST signal may be asserted, thereby pulling the voltage of the local wordline 242 down to VWLOFF. By using a single pull-down transistor 308 driven by WLRST, space occupied by the pull-down transistor 308 on the DRAM die which utilizes the pull-down transistor 308 may be conserved.

Exemplary Layouts of Local Wordlines and Pull-Down Transistors

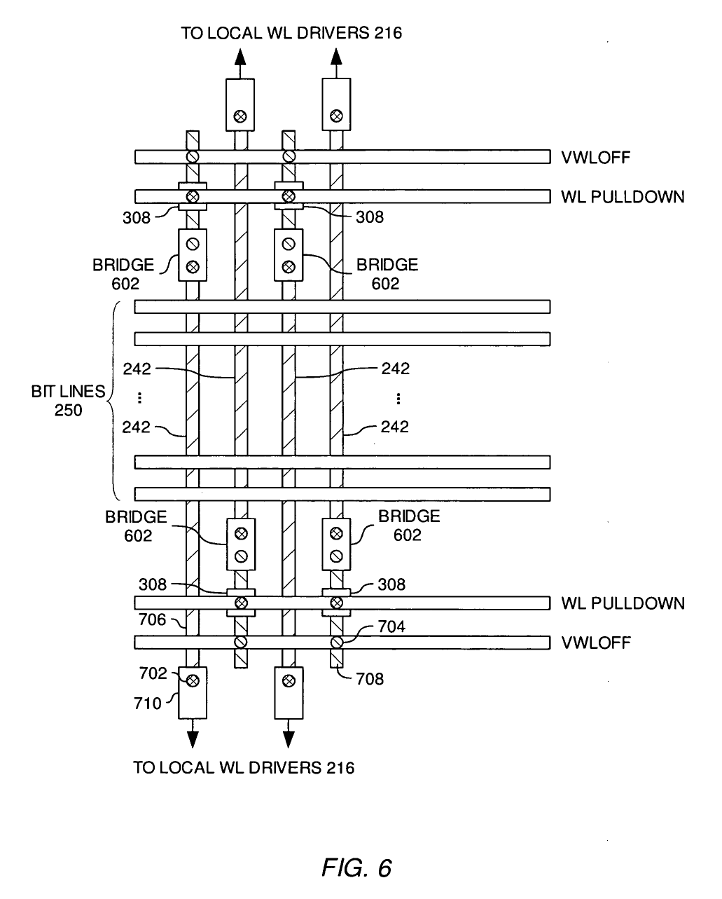

FIG. 6 is a circuit diagram depicting an exemplary layout of a memory array 104 with pull-down transistors 308 according to one embodiment of the invention. In some cases, to conserve area, local wordlines 242 in the memory array 104 may be interleaved, e.g., by placing the local wordline drivers 216 for every other local wordline in the memory array 104 on opposite sides of the bitlines 250 and memory cells being accessed by the local wordlines 242. In one embodiment of the invention, the pull-down transistors 308 may be similarly interleaved by placing the pull-down transistors 308 for every other local wordline 242 on opposite sides of the bitlines 250 and memory cells being accessed by the local wordlines 242. As depicted, bridges 602 (e.g., from the gate conductive layer 706, to a first layer of metal (M1 layer 710), and to the active layer 708) may be used to connect the local wordlines 242 to the pull-down transistors 308.

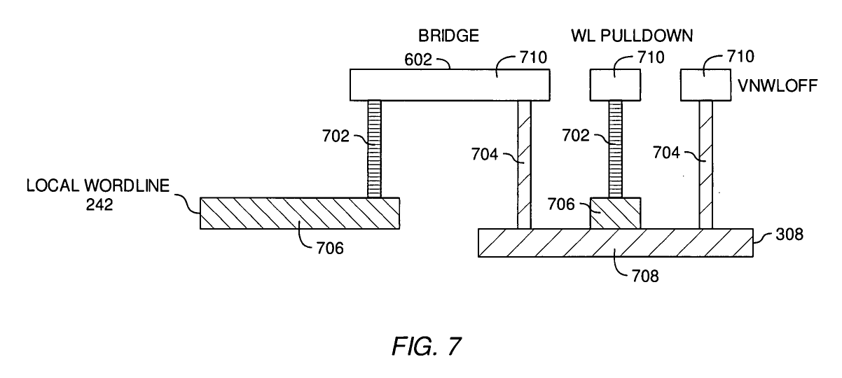

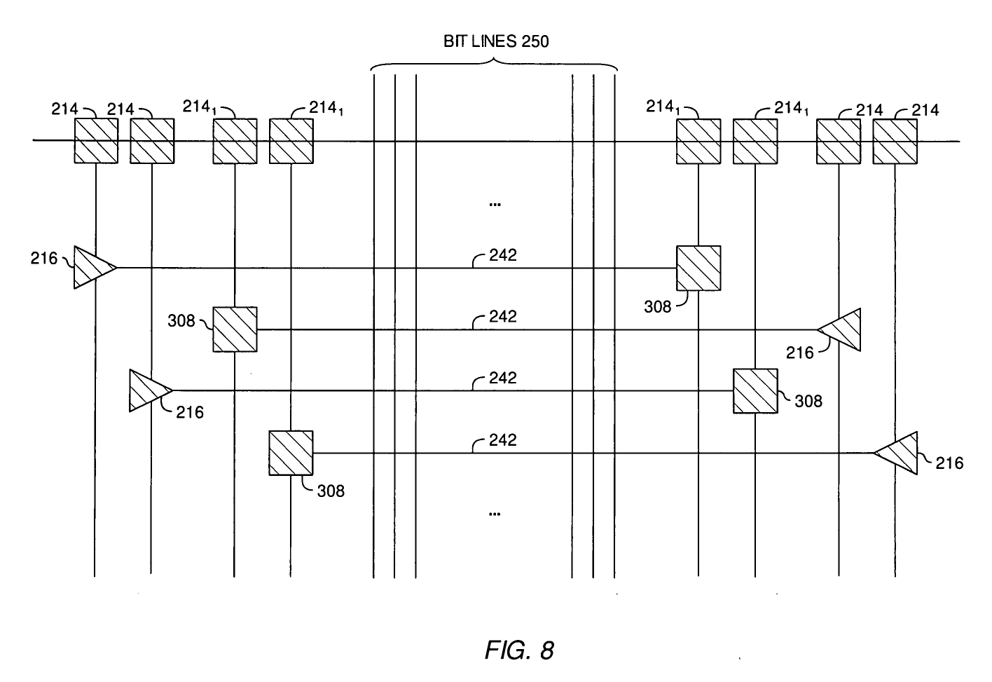

FIG. 7 is a circuit diagram depicting a side view of a pull-down transistor 308 in a memory array according to one embodiment of the invention. As depicted, the bridge 602 between the local wordline 242 and the pull-down transistor 308 may be connected to a gate conductive layer 706 at the end of the local wordline 242 by a via 702 from the gate conductive layer 706 to the M1 layer 710.

The bridge 602 may be connected to the source of the pull-down transistor 308 by a via 704 from the M1 layer 710 to an active layer 708. The gate of the pull-down transistor 308 may be connected to the WL Pulldown signal by a via 702 from the M1 layer 710 to the gate conductive layer 706. The drain of the pull-down transistor 308 may be connected by a via 704 from the active layer 708 to the M1 layer 710.

In some cases, multiple local wordline decoders 214 may be used to activate pull-down transistors 308 in a segmented memory array 104. FIG. 8 is a block diagram depicting additional local wordline decoders 214₁ used to control pull-down transistors 308 in a memory array 104 according to one embodiment of the invention. As depicted, alternating local wordlines 242 may be driven from opposite sides in the memory array 104, allowing the local wordline drivers 216 to be interleaved and thereby conserving space in the memory array 104. Also, the pull-down transistors 308 attached to the opposite sides of the local wordlines 242 from the local wordline drivers 216 may also be interleaved.

As described above, local wordline decoders 214 may be used to generate the wordline reset signal WLRSTp which is used by local wordline drivers 216 to select a local wordline 242 to be accessed. Similarly, the additional local wordline decoders 214₁ may be used to activate the pull-down transistors 308 for local wordlines 242 which are not being accessed. For example, in one embodiment, the additional local wordline decoders 214₁ may generate and apply the WLRSTp signal to the pull-down transistors 308. When the WLRSTp signal is asserted, the pull-down transistors 308 may lower the voltage of the local wordlines 242 which are not being accessed, thereby preventing any floating local wordlines 242 from being inadvertently accessed and preventing any resulting memory loss.

By using additional local wordline decoders 214₁ to control the pull-down transistors 308, redundant control for the pull-down transistors 308 may be provided. Because the pull-down transistors 308 may be redundantly controlled, any localized manufacturing defects in the local wordline decoders 214, the local wordline drivers 216, or the control lines which apply control signals to the local wordline decoders 216 may not affect the additional local wordline decoders 214₁, allowing any floating local wordlines 242 to be correctly pulled-down to the wordline off voltage VWLOFF.

While described above with respect to pull-down transistors 308, any suitable pull-down circuit known to those skilled in the art may be used to apply the wordline off voltage VWLOFF to wordlines which are not activated. Also, while some voltages are described above as being downward-driven low voltages (e.g., VWLOFF) or boosted high voltages (e.g., V_{PP}) driven by a charge pump, embodiments of the invention may be used where such signals are not driven by a charge pump. Embodiments of the invention may also be used to effect where such downward-driven or boosted signals (e.g., VWLOFF or V_{PP}) are replaced with low power supply voltages or high power supply voltages (e.g., V_{GND} or V_{DD}), or with any other voltages which are different with respect to one another.

Furthermore, while the foregoing is directed to embodiments of the present invention, other and further embodiments of the invention may be devised without departing from the basic scope thereof, and the scope thereof is determined by the claims that follow.

What is claimed is:

1. A method for accessing a local wordline in a segmented memory, the method comprising:
during an access to the local wordline, applying a first voltage to the local wordline via a local wordline driver located at a first end of the local wordline; and
after the access is completed, applying a second voltage to the local wordline, wherein the second voltage is applied to the local wordline via a pull-down circuit located at a second end of the local wordline opposite from the first end, wherein one or more memory cells are attached to local wordline between the local wordline driver and the wordline pull-down circuit.

2. The method of claim 1, wherein, after the access is completed, the second voltage is further applied via the local wordline driver located at the one end of the local wordline.

3. The method of claim 1, where the second voltage is applied by the pull-down circuit when a segment in which the local wordline is located is not being accessed.

4. The method of claim 1, where the second voltage is applied by the pull-down circuit only during a precharge state of a segment in which the local wordline is located.

5. The method of claim 1, wherein the local wordline is one of a plurality of local wordlines controlled by a main wordline, and wherein the second voltage is applied by the pull-down circuit to the local wordline when another one of the plurality of local wordlines is being accessed.
Second Method

6. A method for accessing a local wordline in a segmented memory, the method comprising:
receiving a memory address;
determining if the received memory address corresponds to the local wordline;
if the received memory address corresponds to the local wordline, applying a first voltage to the local wordline via a local wordline driver located at one end of the local wordline; and
if the received memory address does not correspond to the local wordline, applying a second voltage to the local wordline, wherein the second voltage is applied to the local wordline via a pull-down circuit located at an opposite end of the local wordline from the one end of the local wordline wherein one or more memory cells are attached to local wordline between the local wordline driver and the wordline pull-down circuit.

7. The method of claim 6, wherein a row decoder and a first local wordline decoder are used to determine if the received address corresponds to the local wordline, and, if so, activate a main wordline and the local wordline driver for the local wordline.

8. The method of claim 7, wherein a second local wordline decoder is used to determine if the received address does not correspond to the local wordline, and if not, activate the pull-down circuit.

9. The method of claim 8, wherein activating the pull-down circuit comprises applying a high voltage to the gate of a transistor, wherein the source of the transistor is connected to the opposite end of the local wordline and wherein the drain of the transistor is connected to the second voltage.

10. The method of claim 6, where the second voltage is applied by the pull-down circuit only during a precharge state of a segment in which the local wordline is located.

11. A memory device comprising:
a local wordline;
a local wordline driver connected to a first end of the local wordline;
a pull-down circuit connected to a second end of the local wordline opposite the first end, wherein one or more memory cells are attached to the local wordline between the first end of the local wordline and the second end of the local wordline; and
circuitry configured to:
during an access to the local wordline, activate the local wordline driver, thereby applying a first voltage to the local wordline; and
after the access to the local wordline, activate the pull-down circuit, thereby applying a second voltage to the local wordline.

12. The memory device of claim 11, wherein the local wordline driver consists of a single pull-down transistor and a single pull-up transistor, and wherein the pull-down circuit consists of a single pull-down transistor.

13. The memory device of claim 11, wherein the second voltage is applied to the local wordline via the pull-down circuit when a segment in which the local wordline is located is not being accessed.

14. The memory device of claim 11, wherein the second voltage is applied by the pull-down circuit only during a precharge state of a segment in which the local wordline is located.

15. The memory device of claim 11, wherein the pull-down circuit comprises an NMOS transistor, wherein a source of the NMOS transistor is connected to the second end of the local wordline and a drain of the NMOS transistor is connected to the second voltage, and wherein activating the pull-down circuit comprises applying an activation voltage to a gate of the NMOS transistor.

16. A DRAM memory device, comprising:
a memory array comprising:
a plurality of segments, wherein each segment comprises:
i) a plurality of local wordlines, and wherein each local wordline comprises:
a local wordline driver connected to a first end of the local wordline; and
a pull down circuit connect to a second end of the local wordline opposite the first end, wherein one or more memory cells are attached to each of the plurality of local wordlines respectively between the first end of each local wordline and the second end of each local wordline; and
ii) a plurality of main wordlines, wherein each main wordline is used to access a corresponding plurality of local wordlines; decoder circuitry configured to:
receive a memory address;
determine if the received memory address corresponds to one of the plurality of local wordlines;
if the received memory address corresponds one of the plurality of local wordlines, apply a first voltage to the one local wordline via the local wordline driver connected to the one local wordline; and
if the received memory address does not correspond to the one local wordline, apply a second voltage to the one local wordline via the respective pull-down circuit of the one local wordline.

17. The DRAM memory device of claim 16, wherein each local wordline driver consists of a single pull-down transistor and a single pull-up transistor, and wherein each pull-down circuit consists of a single NMOS pull-down transistor.

18. The DRAM memory device of claim 16, wherein the second voltage is applied to each local wordline only during a precharge state of the segment in which the local wordline is located.

19. The DRAM memory device of claim 16, wherein the second voltage is applied to each local wordline in a segment via the corresponding pull-down circuit for the local wordline when the segment in which the local wordline is located is not being accessed.

20. The DRAM memory device of claim 16, wherein each pull-down circuit comprises an NMOS transistor, wherein a source of the NMOS transistor is connected to the corresponding local wordline and a drain of the NMOS transistor is connected to the second voltage, and wherein applying the second voltage comprises applying an activation voltage to a gate of the NMOS transistor.

21. A memory device comprising:
a local wordline;
means for driving a local wordline connected to a first end of the local wordline;
a means for applying a voltage connected to a second end of the local wordline opposite the first end, wherein one or more memory cells are attached to the local wordline between the first end of the local wordline and the second end of the local wordline; and
means for accessing configured to:
during an access to the local wordline, activate the local wordline driver, thereby applying a first voltage to the local wordline; and
after the access to the local wordline, activate the pull-down circuit, thereby applying a second voltage to the local wordline.

22. The memory device of claim 21, wherein the means for driving a local wordline consists of a single pull-down transistor and a single pull-up transistor, and wherein the a means for applying a voltage consists of a single pull-down transistor.

23. The memory device of claim 21, wherein the second voltage is applied to the local wordline via the means for applying a voltage when a segment in which the local wordline is located is not being accessed.

24. The memory device of claim 21, wherein the second voltage is applied by the means for applying a voltage only during a precharge state of a segment in which the local wordline is located.

25. The memory device of claim 21, wherein the a means for applying a voltage comprises an NMOS transistor, wherein a source of the NMOS transistor is connected to the second end of the local wordline and a drain of the NMOS transistor is connected to the second voltage, and wherein activating the a means for applying a voltage comprises applying an activation voltage to a gate of the NMOS transistor.
